(19) United States
(12) Patent Application Publication
(10) Pub. No.: US 2002/0140050 A1
(43) Pub. Date: Oct. 3, 2002

(54) Semiconductor device having an inductor with low loss

(76) Inventors: Kjell Bohlin, Uppsala (SE); Ulf Magnusson, Uppsala (SE); Ola Tylstedt, Vallingby (SE)

Correspondence Address: BURNS DOANE SWECKER & MATHIS L L P, POST OFFICE BOX 1404, ALEXANDRIA, VA, 22313-1404, US

(21) Appl. No.: 09/503,346

(22) Filed: Feb. 14, 2000

(30) Foreign Application Priority Data
Feb. 15, 1999 (SE) 9900498-8

(51) Int. Cl. H01L 29/00

(52) U.S. Cl. 257/528

(57) ABSTRACT

The present invention relates to an integrated circuit for high-frequency applications, comprising a substrate (31) of high resistivity, active components (37, 41) and an inductor (45) above said substrate, whereby the active components and the inductor are arranged laterally mainly separated. According to the invention a layer (33) of low resistivity is comprised below the active components and laterally separated from the inductor. The invention also relates to a method for manufacturing said semiconductor device, which particularly comprises adding two new process steps, a masking step and a doping step, respectively, to a known process.

### TECHNICAL FIELD

The present invention relates partly to an integrated circuit for high-frequency applications, comprising a substrate, active components and an inductor, partly to a method in the manufacturing of such an integrated circuit.

### RELATED ART

Inductors, e.g. coils, for integrated circuits may be manufactured separate from or together with the integrated circuits on a substrate. In the latter case the inductors are normally manufactured by patterning coils in some of the upper metal layers that are used for connection of components comprised in the integrated circuits.

The quality factor of these coils is heavily limited by losses to the substrate as a consequence of eddy currents being induced in said substrate.

The eddy currents may be reduced by removing the substrate locally beneath an inductor, which, however, implies complicated process technology, see WO 9,417,558 and U.S. Pat. No. 5,773,870.

In the former publication is described the etching of a window around the inductor, whereafter the substrate beneath the inductor is etched away. The drawbacks of this method are, except the technical complexity of the process, that the etching is difficult to control, implying low yield levels, and that the windows take up a significant substrate volume.

The American patent describes an integrated circuit with an inductor of a membrane type (with a cavity beneath the inductor achieved by etching from the backside of the substrate). The inductor takes up a relatively large space, also in this case, at the same time as the circuit is very easily damaged due to that the thickness of the membrane is only a few micrometers.

Another solution comprises providing an inductor over a layer of an insulating oxide formed by oxidizing part of a SOI layer (Silicon On Isolator) deposited on top of a silicon substrate of high resistivity, wherein semiconductor components are arranged in the remaining SOI layer, see for instance the Japanese Patent Publication JP 09,270,515. The drawbacks of this structure are i.a. that it is expensive and complicated to deposit an SOI layer, which often gives rise to components of a relatively low quality. Besides, the insulation layer prevents effectively all heat transports to/from the substrate.

A further possibility to minimize substrate losses is simply to raise the resistivity of the underlying substrate, see the American Patent U.S. Pat. No. 5,559,349. This solution gives, however, particularly in large densely-packed circuits, problems of so-called latch-up, which means that parasitic thyristors are switched on and lock the circuit in an undesired state.

For high quality close-packed integrated circuits there is today no known technology to achieve inductors with sufficiently high quality factors, i.e. low losses, integrated on a semiconductor substrate.

### SUMMARY OF THE INVENTION

There is an object of the present invention to provide an integrated circuit, which comprises a substrate, active components and an inductor, which circuit exhibits improved performance in comparison with known technology.

There is in this context a particular object of the invention to provide said semiconductor device, whose inductor exhibits low losses to the substrate and whose active components have very low or non-existing tendency to be locked through so-called latch-up.

There is a further object of the present invention to provide a robust, cheap and reliable integrated circuit of the above-mentioned kind.

There is yet a further object of the invention to provide at least one method for the manufacturing of said integrated circuit.

In this respect it is a particular object of the invention to provide a simple and cheap manufacturing method compatible with conventional volume production, such as VLSI (Very Large-Scale Integration) production, of integrated circuits.

Yet other objects of the present invention will be apparent in the specification below.

According to a first aspect of the present invention these objects are attained by an integrated circuit for high-frequency applications, comprising a semiconductor substrate of high resistivity, active components in said substrate and an inductor above said substrate, the active components and the inductor being arranged substantially separated in the lateral dimension, and a layer of low resistivity being arranged beneath the active components and separated from the inductor in the lateral dimension.

The substrate of high resistivity is preferably of high resistivity for the purpose of attaining an inductor that exhibits low substrate losses and the layer of low resistivity is preferably of sufficiently low resistivity, so that the circuit device avoids latch-up.

The inductor of the integrated circuit can be designed as a coil in some, preferably upper, metal layer, particularly in a layer that is used for electrical connection in said integrated circuit.

According to a second aspect of the present invention there is provided an integrated circuit, preferably for high-frequency applications, comprising a substrate of a semiconductor material of high resistivity, a layer of said semiconductor material thereon, active components in said layer and an inductor above said layer, the active components and the inductor being arranged mainly separated in a lateral dimension, and there is provided a layer of low resistivity beneath said active components and laterally separated from the inductor.

According to a third aspect of the present invention there is provided a method in the fabrication of an integrated circuit, preferably intended for high-frequency applications, comprising the steps of:

providing a substrate of a semiconductor material of high resistivity,

forming active components in said substrate,

forming an inductor above said substrate and in the lateral direction mainly separated from said active components,

forming a layer of low resistivity beneath said active components and separated from the inductor in a lateral direction.

According to a fourth aspect of the present invention there is provided a method in the fabrication of an integrated circuit, preferably intended for high-frequency applications, comprising the steps of:

providing a substrate of a semiconductor material of high resistivity,

forming a layer of the same semiconductor material thereon,

forming active components in said layer,

forming an inductor above said layer and in the lateral direction mainly separated from said active components,

forming a layer of low resistivity beneath said active components and separated from the inductor in the lateral direction.

An advantage of the present invention is that a compact semiconductor device comprising an inductor of low losses, i.e. with a high quality factor, a so-called Q factor, is achieved.

Further advantages of the invention will be apparent in the specification below.

The invention will be closer described below with reference to the attached drawings, which are only shown to illustrate the invention, and shall therefore in no way limit the same.

### SHORT DESCRIPTION OF THE DRAWINGS

FIG. 1 illustrates, in cross-section, a known semiconductor device comprising a substrate, a circuit device and an inductor, whereby the substrate is of low resistivity.

FIG. 2 illustrates, in cross-section, yet another known semiconductor device comprising a substrate, a circuit device and an inductor, whereby the substrate is of high resistivity.

FIG. 3 illustrates, in cross-section, a semiconductor device according to one embodiment of the present invention.

### PREFERRED EMBODIMENTS

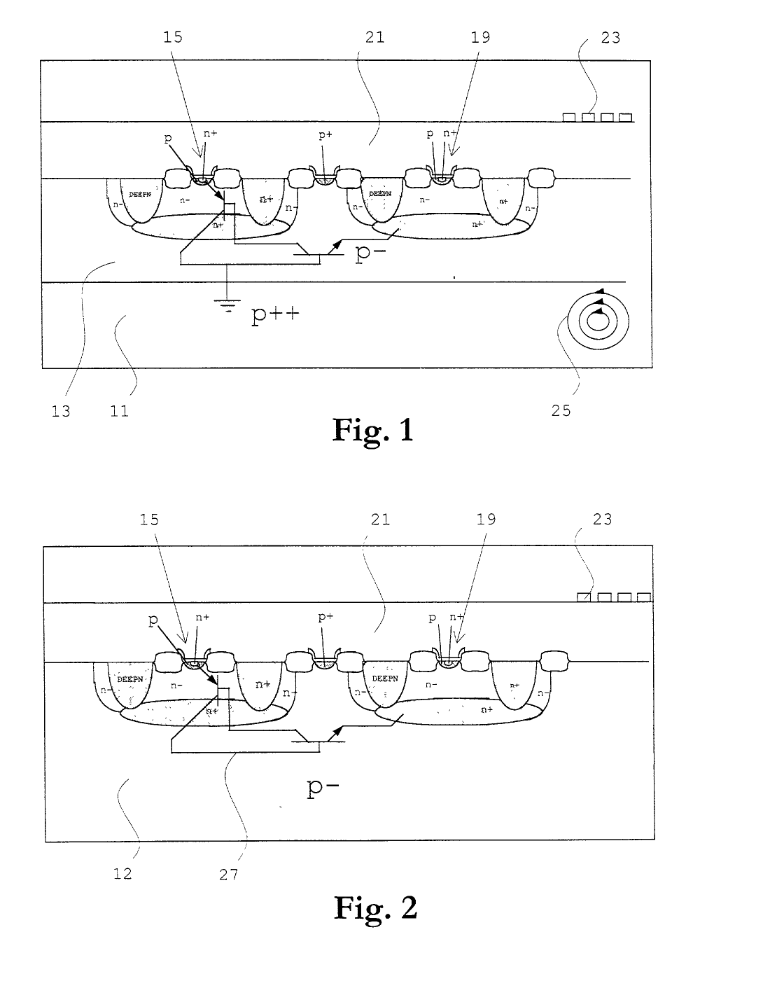

With reference to FIG. 1 a previously known semiconductor device comprises a silicon substrate 11 of low resistivity, doped to p⁺⁺, on top of which an epitaxial layer 13 of high resistivity, doped to p⁻, is deposited. In the epilayer 13 is part of a circuit device (integrated circuit), comprising a number of components, of which two transistors 15, 19 of npn type are shown in the figure, manufactured. Above the active components there may exist a number of layers, comprising i.a. metallic layers for electric connections, which in the figure are only indicated as one relatively thick layer 21. In one or more of the metallic layers is an inductor 23 comprised in the circuit manufactured. The inductor may thus be manufactured together with an integrated circuit on a chip.

A problem of this design is that the quality factor of the inductor 23 is heavily limited by losses to the substrate 11. These losses arise due to eddy currents, indicated with 25 in FIG. 1, being induced in said substrate.

With reference now to FIG. 2 yet another previouly known semiconductor device is described. The same reference numeral as used in FIG. 1 is used also in this figure to indicate identical layers, circuits, components or the like. Thus, the semiconductor device comprises a substrate 12 of high resistivity, doped to p⁻, in which substrate part of a circuit device, comprising a number of components, of which two transistors 15, 19 of npn type are shown, is manufactured. Not defined layers lying above are indicated as earlier with 21. An inductor 23, connected to the circuit device, is manufactured in one or more metallic layers.

With this design losses to the substrate are avoided. However, the risk of so-called latch-up is increased, which means that parasitic thyristors are switched on and lock the circuit in an undesired state, see the overlaid circuit scheme indicated by 27 in FIG. 2. This is particularly the case in large close-packed circuits.

The present invention aims to solve the problem of the losses in the substrate while observing a maintained immunity to latch-up. The known technology to achieve this involves complicated process steps, which are not compatible with volume production of integrated circuits, see the discussion under related art.

The proposed solution means in brief that a substrate of high resistivity is utilized, on which a layer of low resistivity is achieved locally below active components that have a tendency to be locked through latch-up and a layer of high resistivity locally below areas where inductors are to be defined. The layer of low resistivity is thereafter contacted in a suitable manner.

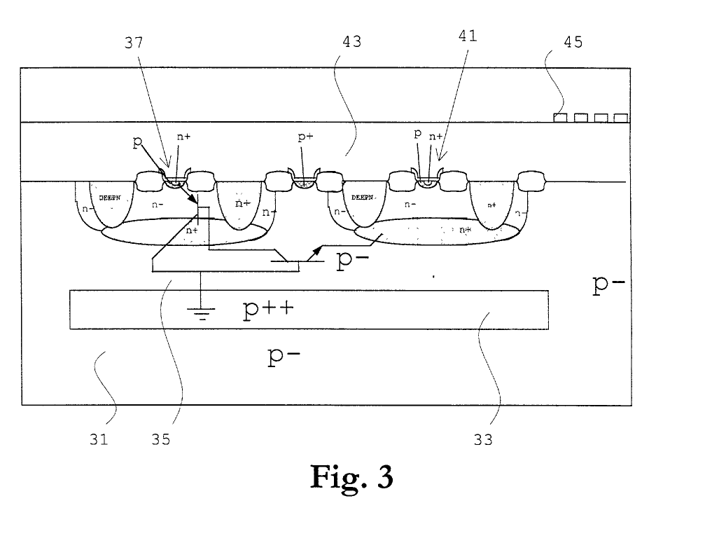

An inventive embodiment of a semiconductor device is shown in FIG. 3. On a substrate 31 of high resistivity, particularly of silicon, doped to p⁻, a mask (not shown) with openings according to the planned active components and inductors of the semiconductor device, is placed. Doping through the openings of the mask is achieved preferably by ion implantation, whereby a local p⁺⁺ doped region 33 of low resistivity is formed.

Alternatively, instead of letting the region 33 constitute part of a substrate wafer, a crystalline, preferably epitaxial, layer of high resistivity may be deposited on the substrate wafer, in which layer the region 33 is formed.

Above the obtained structure a crystalline layer 35 of high resistivity is deposited, in which layer and mainly straight above the local layer of low resistivity an integrated circuit device is formed. The layer 35 is preferably deposited epitaxially, but a crystalline layer may be deposited in another manner, for instance by bonding.

As a further alternative the layer 33 of low resistivity may be formed inside the substrate through for instance ion implantation. By choosing suitable ion implantation energy the layer may be formed at a suitable depth, whereby the circuit device advantageously is manufactured directly in the substrate.

Part of the circuit device, namely two transistors 37, 41, are shown in FIG. 3. Above these active components a number of not defined layers may be deposited, which are indicated by 43 in the figure.

In any or some of the layers, preferably upper the layers, of the chip an inductor 45 is formed, which inductor shall be placed in lateral direction separated from the layer 33 of low resistivity. The inductor 45 is preferably designed as a coil in some of the metallic layers situated high up, particularly in layers that are used for electric connection in said circuit device 37, 41. The inductor is thus monolithically integrated with an integrated circuit on a chip.

It shall in this respect also be noted that only two further process steps, namely the above-mentioned masking and doping steps, respectively, are added to a known process technology compatible with volume production, particularly VLSI (Very Large-Scale Integration) technology.

The substrate 31 of high resistivity is advantageously arranged in such a way, preferably of sufficiently high resistivity, e.g. at least 1 Ωcm, that the inductor 45 shows low substrate losses and that the layer 33 of low resistivity is arranged in such a way, preferably of sufficiently low resistivity, e.g. not more than 0.5 Ωcm, that the circuit device 37, 41 avoids latch-up.

The distance between the layer 33 of low resistivity and the circuit device 37, 41 is in one embodiment below approximately 10 um. It ought to be ensured in the lateral direction a certain distance of safety between the layer 33 of low resistivity and the inductor 45.

In practice, the chip may contain a number of circuit devices and one or several inductors. It is in this respect possible to arrange the layer of low resistivity everywhere except of just below the inductor or the inductors, preferably with regard to the above-mentioned safety distance in the lateral direction, whereby the term local layer of low resistivity possibly may appear improper. Here, it is rather spoken of local “islands” of high resistivity below the inductors.

The layer 33 of low resistivity may thereafter be contacted in different ways to ensure a controlled potential below the regions with active components.

An advantage of the present invention is that it uses known process technology for the manufacturing of integrated circuits, entirely compatible with volume production. The advantages of a substrate of high resistivity for inductors of low losses are combined with the advantages of a substrate of low resistivity for stability in other parts of the integrated circuit.

The invention is of course not limited to the embodiments described above and shown in the drawings, but may be modified within the scope of the attached claims. Particularly, the invention is apparently not limited to the types of doping, materials, dimensions or the manufacturing methods of the semiconductor device as found in this specification.

1. An integrated circuit, preferably for high-frequency applications, comprising a semiconductor substrate (31) of high resistivity, active components (37, 41) in said substrate and an inductor (45) above said substrate, the circuit device and the inductor being arranged laterally mainly separated, wherein a layer (33) of low resistivity is arranged below said active components (37, 41) and laterally separated from the inductor (45).

2. The integrated circuit as claimed in claim 1, wherein the layer (33) of low resistivity is comprised of part of the semiconductor substrate, which part is doped to low resistivity.

3. The integrated circuit as claimed in claim 1, wherein the substrate (31) has a high resistivity for the purpose of attaining an inductor (45) of low substrate losses and the layer (33) of low resistivity has a sufficiently low resistivity in order that said active components (37, 41) will avoid latch-up.

4. The integrated circuit as claimed in claim 1, wherein the inductor (45) is comprised of a coil in some, preferably upper, metallic layer, particularly in a layer, which is used for electrical connection of said active components (37, 41).

5. The integrated circuit as claimed in claim 1, wherein the distance between the layer (33) of low resistivity and said active components (37, 41) is less than approximately 10 um.

6. The integrated circuit as claimed in claim 1, wherein the substrate of high resistivity has a resistivity of above 1 Ωcm and the layer (33) of low resistivity has a resistivity of less than 0.5 Ωcm.

7. The integrated circuit as claimed in claim 1, wherein the inductor (45) and the active components (37, 41) are monolithically integrated.

8. The integrated circuit as claimed in claim 1, wherein said semiconductor material is silicon.

9. The integrated circuit as claimed in claim 1, wherein it is arranged with a certain safety distance in the lateral direction between the layer of low resistivity (33) and the inductor (45).

10. An integrated circuit, preferably for high-frequency applications, comprising a substrate (31) of a semiconductor material of high resistivity, a layer of said semiconductor material thereon, active components (37, 41) in said layer and an inductor (45) above said layer, wherein the active components and the inductor are arranged mainly separated in the lateral direction and a layer (33) of low resistivity is arranged beneath the active components (37, 41) and separated from the inductor (45) in the lateral direction.

11. The integrated circuit as claimed in claim 10, wherein the layer, in which the active components are formed, is an epitaxial layer.

12. The integrated circuit as claimed in claim 10, wherein the layer (33) of low resistivity is formed between the substrate and the layer, in which the active components are formed.

13. The integrated circuit as claimed in claim 10, wherein the layer (33) of low resistivity is comprised of part of the substrate, which part is doped to low resistivity.

14. The integrated circuit as claimed in claim 10, wherein the layer (33) of low resistivity is comprised of part of the layer, in which the active components are formed, which part is doped to low resistivity.

15. The integrated circuit as claimed in claim 10, wherein the substrate (31) has a high resistivity for the purpose of attaining an inductor (45) of low substrate losses and the layer (33) of low resistivity has a sufficiently low resistivity in order that the active components (37, 41) will avoid latch-up.

16. The integrated circuit as claimed in claim 10, wherein the distance between the layer (33) of low resistivity and said active components (37, 41) is less than approximately 10 um.

17. The integrated circuit as claimed in claim 10, wherein the substrate (31) of high resistivity has a resistivity of above 1 Ωcm and the layer (33) of low resistivity has a resistivity of less than 0.5 Ωcm.

18. A method in the fabrication of an integrated circuit, preferably intended for high-frequency applications, comprising the steps of:
providing a substrate (31) of a semiconductor material of high resistivity,
forming active components (37, 41) in said substrate,
forming an inductor (45) above said substrate and in the lateral direction mainly separated from said active components (37, 41),
wherein
a layer (33) of low resistivity is formed beneath said active components (37, 41) and separated from the inductor (45) in a lateral direction.

19. The method as claimed in claim 18, wherein the layer (33), which is formed beneath said active components (37, 41), is achieved through a masking step and a doping step prior to the formation of said active components and the inductor, where said masking step comprises placing a mask having openings in accordance with the planned active components of the integrated circuit above the substrate, and said doping step comprising doping the substrate through the openings of the mask, preferably through ion implantation.

20. The method as claimed in claim 18, wherein it is performed by using a technology, such as VLSI (Very Large-Scale Integration), which is suitable for volume production.

21. A method in the fabrication of an integrated circuit, preferably intended for high-frequency applications, comprising the steps of:
providing a substrate (31) of a semiconductor material of high resistivity,
forming a layer of the same semiconductor material thereon,
forming active components (37, 41) in said layer,
forming an inductor (45) above said layer and in the lateral direction mainly separated from said active components (37, 41),
wherein
a layer (33) of low resistivity is formed beneath said active components (37, 41) and separated from the inductor (45) in the lateral direction.

22. The method as claimed in claim 21, wherein the layer (33) of low resistivity is formed through epitaxial deposition.

23. The method as claimed in claim 21, wherein the layer (33) of low resistivity is formed between the substrate and the layer, in which the active components are formed.

24. The method as claimed in claim 21, wherein the layer (33) of low resistivity is formed in the layer, in which the active components are formed, through doping.

25. The method as claimed in claim 21, wherein the layer (33) of low resistivity is achieved through a masking step and a doping step prior to the formation of the active components and the inductor, where said masking step comprises placing a mask having openings in accordance with the planned active components of the integrated circuit above the substrate and said doping step comprises doping the substrate through the openings of the mask, preferably through ion implantation.

26. The method as claimed in claim 21, wherein it is performed by using a technology, which is compatible with volume production, such as VLSI (Very Large-Scale Integration).
